(19) United States
(12) Patent Application Publication
(10) Pub. No.: US 2006/0245226 A1
(43) Pub. Date: Nov. 2, 2006

(54) Fully buffered DIMM architecture and protocol

(75) Inventor: Heath Stewart, Santa Barbara, CA (US)

Correspondence Address: KOPPEL, PATRICK & HEYBL, 555 ST. CHARLES DRIVE, SUITE 107, THOUSAND OAKS, CA, 91360, US

(73) Assignee: INPHI CORPORATION

(21) Appl. No.: 11/120,913

(22) Filed: May 2, 2005

(51) Int. Cl. G11C 19/08

(52) U.S. Cl. 365/22

(57) ABSTRACT

A FB DIMM architecture and protocol comprises a memory controller, which is serially-connected to first and second DIMMs via southbound (SB) and northbound (NB) data paths to form a first channel, and to third and fourth DIMMs via SB and NB paths to form a second channel. Each DIMM comprises a plurality of RAM devices, and an AMB device arranged to receive data from the SB and NB paths, to encode/decode data for each of the DIMM's RAM devices, and to redrive data received from the SB or NB paths to the next device on the respective data paths. The system's protocol is arranged such that the bits of any given data word are interleaved across the RAM devices such that each RAM stores no more than one bit of the data word.

### BACKGROUND OF THE INVENTION

1. Field of the Invention

This invention relates to memory architectures, and particularly to memory architectures employing fully buffered DIMMs.

2. Description of the Related Art

Many schemes have been developed for the organization and operation of random access memory (RAM) devices accessed by a microprocessor. One traditional “stub bus” RAM architecture, in this case for a DDR memory channel, is shown in FIG. 1. Here, a number of “dual inline memory modules” (DIMMs) 10, 12 contain a number of individual RAM chips 14. The DIMMs interface with a host 16 via a parallel data bus 18 and a control/address bus 20. The host writes data to or reads data from the DIMMs by putting the appropriate address on control/address bus 20, which causes each RAM to be simultaneously addressed. The RAM chips are typically arranged to store 4 bits (known as an “x4” chip) or 8 bits (“x8”) at each unique address location. In response to, for example, a read request, each RAM outputs the group of bits stored at the specified address, all of which are conveyed in parallel to data bus 18 and then to host 16.

However, the architecture of FIG. 1 is subject to some limitations. Due to loading factors and the distances between the host and the outermost DIMMs, the maximum clock frequency for a given number of DIMMs is limited. For example, the maximum clock frequency of a channel with 4 DIMMs is typically around 266 MHz. At higher clock frequencies, the channel capacity degrades to 3, 2, and eventually one DIMM per channel. Thus, the stub bus architecture imposes an upper limit on the amount of RAM chips, and thus memory capacity, that can be supported.

Some applications, such as a server computer, require access to large quantities of RAM-often more than can be provided using the stub bus architecture of FIG. 1. One alternative architecture intended to overcome this limitation is shown in FIG. 2, which depicts a “fully buffered” (FB) DIMM memory channel. In accordance with specifications promulgated by JEDEC, an FB-DIMM memory channel is a high speed serial interface, which includes a host 30 and up to 8 DIMMs 32, 33, 34, 35. Each DIMM includes a number of individual RAM chips 36, and an “advanced memory buffer” (AMB) device 38. Data is written to the DIMMs via a “southbound” (SB) data path 40 that serially connects the host 30 to each DIMM, and is read from the DIMMs via a “northbound” (NB) data path 42 that serially connects each DIMM to host 30. SB and NB data is assembled into JEDEC-specified ‘data frames’, with each NB data frame made up of two ‘half frames’. The AMB on each DIMM receives SB and NB data, decodes/encodes the data for its local RAM chips, and redrives the data to the next DIMM in the chain. Thus, data received by DIMM 32 from the host via SB path 40 is redriven to DIMM 33, then DIMM 34, and finally DIMM 35 via the SB path. Data is returned to host 30 in the same manner, via NB path 42. Because SB and NB data is buffered by each DIMM, the loading and distance problems inherent in the stub bus architecture are overcome.

As before, each RAM chip stores a group of bits at each unique address. A given data word is generally stored on a particular DIMM, with its data bits typically distributed across all the RAM chips on the DIMM. For example, assuming a DIMM contains nine x8 RAM chips, a 72-bit data word is stored with 8 bits on each of the nine chips. When host 30 sends a ‘read’ command to a particular address, the RAM chips of the appropriate DIMM each deliver their 8 bits to the AMB, which assembles them into a half frame for return to the host via the NB data path.

However, the architecture of FIG. 2 also suffers from a drawback, in that the failure of a single RAM chip may make some ‘reads’ impossible to perform. Should any given RAM chip fail, all of its stored bits become inaccessible. Thus, for the example above, 8 bits of the 72-bit data word would be lost. Data words often include additional “error correction code” (ECC) bits which typically enable one or two lost or corrupted bits to be recovered. However, it is impractical to employ the number of ECC bits that would be needed to correct for the loss of 4 or 8 bits.

One technique used to enable memory systems to tolerate a failed RAM chip is referred to as a “chipkill” implementation. Here, a memory array is architecturally partitioned to spread out an ECC-enhanced data word over many RAM chips such that any individual chip contributes only one bit of the data word - thereby enabling a data word to be recovered using ECC bits even if an entire RAM chip fails.

Applying the chipkill technique to an FB DIMM architecture as described above would require modifying the FIG. 2 configuration. To keep latency to a reasonable level, instead of one memory channel with 4 serially-connected DIMMs, there are four memory channels interfaced to the host, each of which contains at least one DIMM. Each of the four channels would typically interface to the host via 100-150 I/O pins. Therefore, such an arrangement would require 400-600 I/O pins and a correspondingly large area on a PC board, which may be inconvenient or impractical in many applications.

### SUMMARY OF THE INVENTION

A FB DIMM architecture and protocol is presented which overcomes the problems noted above, providing the advantages of a fully buffered architecture while also enabling the system to successfully tolerate the failure of a RAM chip.

The present architecture and protocol comprises a memory controller (host), a first memory channel with first and second DIMMs, and a second memory channel with third and fourth DIMMs. SB and NB data paths are connected between the controller and the first DIMM and between the first DIMM and the second DIMM such that the first and second DIMMs are serially-connected to the controller. Another pair of SB and NB data paths serially-connects the controller with the third and fourth DIMMs. The SB data paths are used to write the data bits of x-bit wide data words from the controller to the first, second, third and fourth DIMMs, and the NB data paths are used to read the data bits of x-bit wide data words from the first, second, third and fourth DIMMs to the controller.

Each DIMM comprises a plurality of RAM devices, each of which is arranged to store y bits of data at respective addresses, with each DIMM containing x/y RAM chips. Each DIMM also includes an AMB device arranged to receive data from the SB and NB data paths, to encode and decode data for each of the DIMM's RAM devices, and to redrive data received from the SB path to the next device on the SB path, and to redrive data received from the NB path to the next device on the NB path.

To enable the present system to tolerate the failure of a single RAM chip, the system's protocol is arranged such that the bits of any given data word stored in the first and second memory channels are interleaved across the RAM devices such that each RAM stores no more than one bit of the data word. As such, the failure of a RAM chip results in the loss of just one bit of a given data word, which can be corrected via the word's ECC (if used).

Further features and advantages of the invention will be apparent to those skilled in the art from the following detailed description, taken together with the accompanying drawings.

### BRIEF DESCRIPTION OF THE DRAWINGS

FIG. 1 is a diagram of a known stub bus memory architecture.

FIG. 2 is a diagram of a known FB DIMM memory architecture.

FIG. 3 is a diagram of a two memory channel implementation of the present FB DIMM architecture and protocol.

FIG. 4 is a diagram of a four memory channel implementation of the present FB DIMM architecture and protocol.

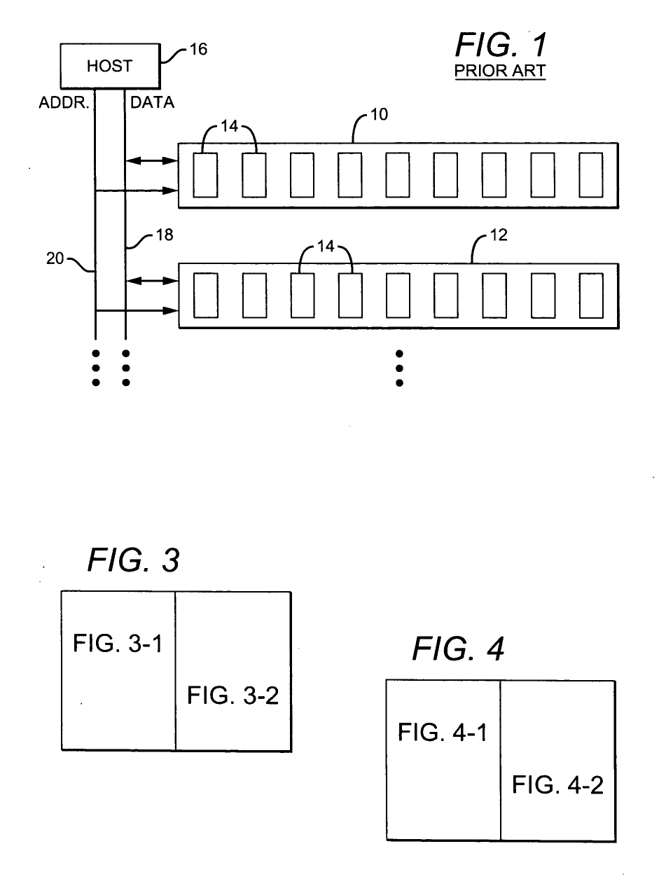

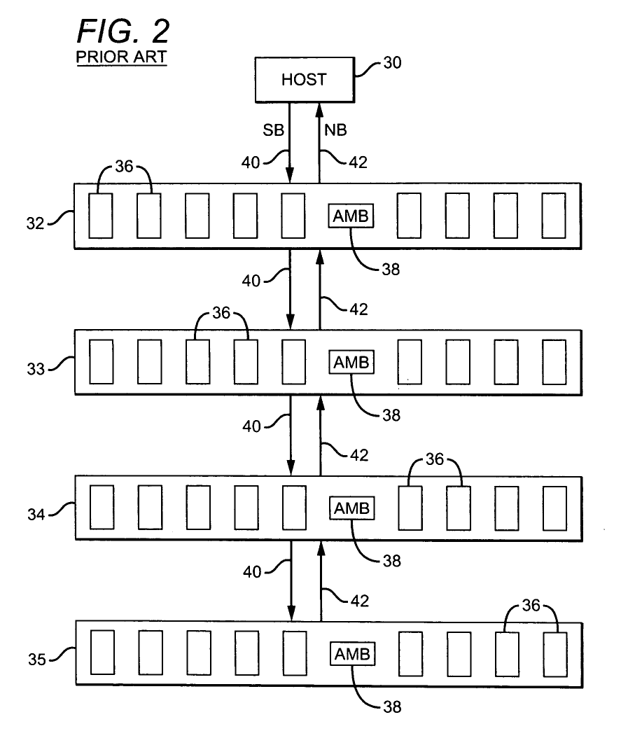

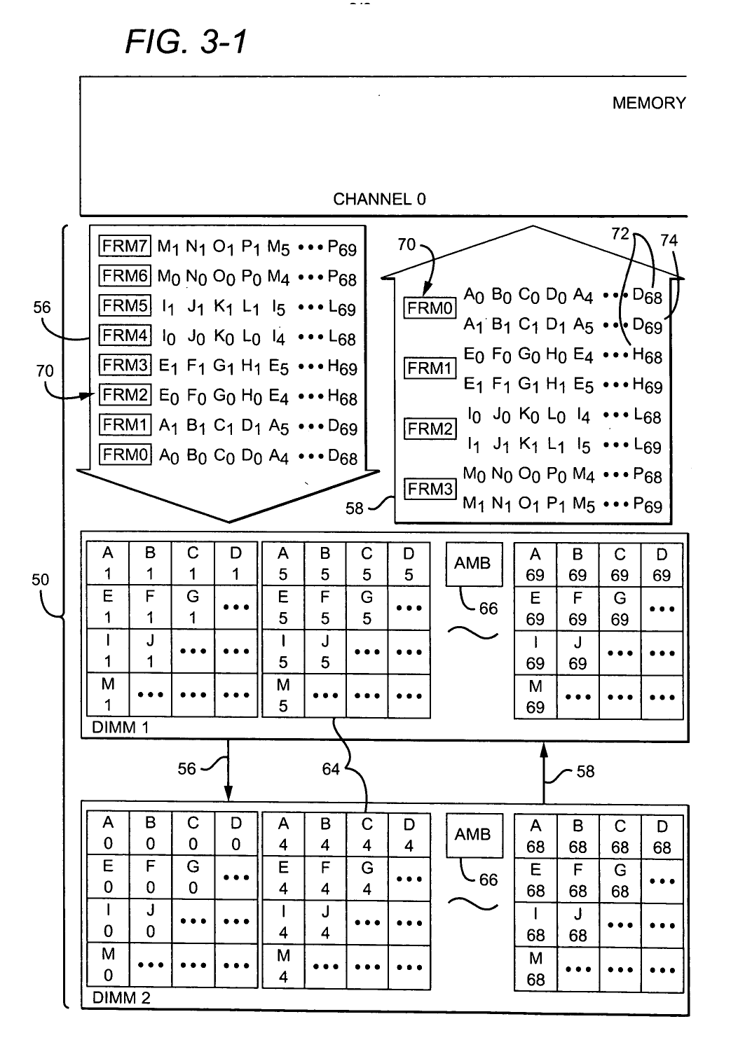

### DETAILED DESCRIPTION OF THE INVENTION

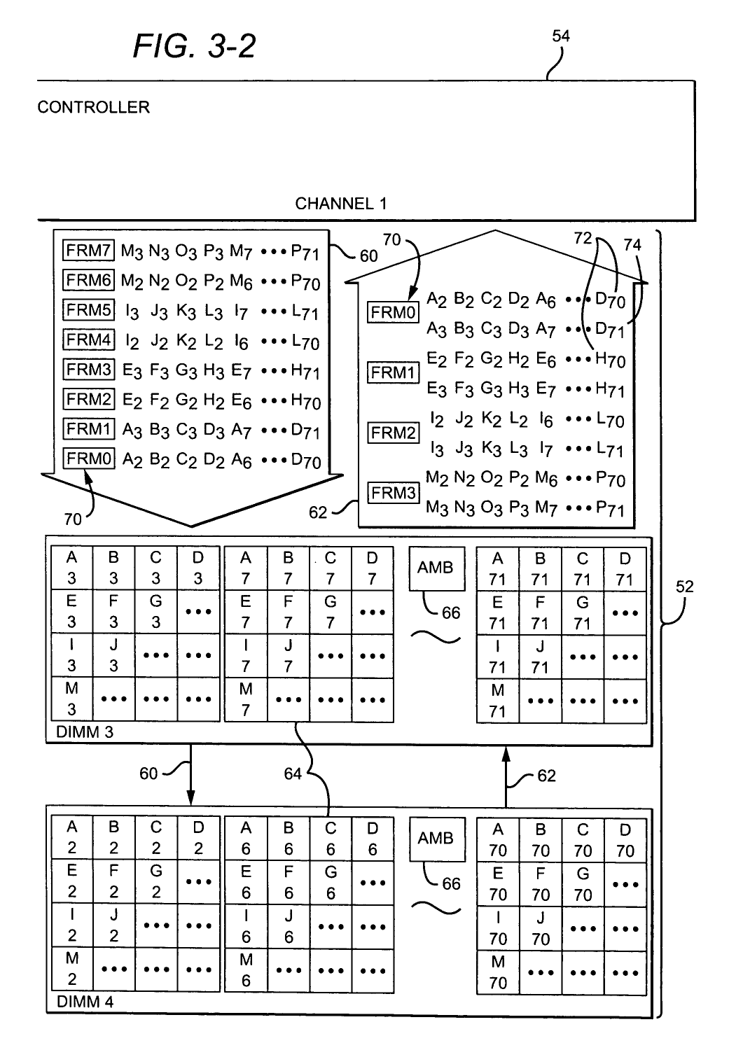

One possible embodiment of a FB DIMM architecture and protocol in accordance with the present invention is illustrated in FIG. 3. In this example, data words written to and read from memory are 72 bits in length, each RAM chip is organized as a “x4” device, meaning it stores 4 data bits at each unique address, and there are two memory channels. Note, however, that this illustration is merely exemplary; the invention may be applied to memory systems having more than two channels, with data words having a length other than 72-bits, and/or with RAM chips which are differently organized than the x4 chips shown in FIG. 3. The RAM chips are typically DRAM devices, but other types of RAM could also be used with the present invention.

In the exemplary embodiment shown, first and second memory channels (Channel 0 and Channel 1) 50 and 52 are interfaced to a memory controller 54. First memory channel 50 includes a first DIMM (DIMM 1) and a second DIMM (DIMM 2). The channel includes a southbound (SB) data path 56 by which data bits of 72-bit wide data words are written to DIMM 1 and DIMM 2, and a northbound (NB) data path 58 by which data bits are read from DIMM 1 and DIMM 2. The SB and NB data paths are connected between memory controller 54 and DIMM 1 and between DIMM 1 and DIMM 2 such that DIMM 1, DIMM 2 and memory controller 54 are serially-connected.

The second memory channel (Channel 1) is similarly configured, containing a third DIMM (DIMM 3) and a fourth DIMM (DIMM 4) serially-connected to controller 54, with a SB data path 60 by which data bits are written to DIMM 3 and DIMM 4, and a NB data path 62 by which data bits are read from DIMM 3 and DIMM 4.

Each DIMM includes a plurality of RAM devices 64 and an AMB 66. In general, when data words x bits in length are stored using the first and second memory channels, and each RAM device is arranged to store y bits of data at respective addresses, each DIMM will contain x/y RAM chips. For this example, x=72 and y=4; therefore, each DIMM contains 18 RAM chips.

Each AMB is arranged to receive data from a channel's SB and NB data paths, to encode/decode data for each of the DIMM's RAM devices, to redrive data received from the SB path to the next device on the SB path, and to redrive data received from the NB path to the next device on the NB path. Thus, for the example illustrated in FIG. 3, the AMB in DIMM 1 receives data from SB data path 56 and NB data path 58, encodes/decodes data for each of DIMM 1's RAM devices, redrives data received from SB path 56 to the AMB in DIMM 2, and redrives data received from the AMB in DIMM 2 via NB path 58 to memory controller 54. The AMB in DIMM 2 receives data from SB data path 56, encodes/decodes data for each of DIMM 2's RAM devices, and drives data to the AMB in DIMM 1 via NB path 58.

Similarly, the AMB in DIMM 3 receives data from SB data path 60 and NB data path 62, encodes/decodes data for each of DIMM 3's RAM devices, redrives data received from SB path 60 to the AMB in DIMM 4, and redrives data received from the AMB in DIMM 4 via NB path 62 to memory controller 54. The AMB in DIMM 4 receives data from SB data path 60, encodes/decodes data for each of DIMM 4's RAM devices, and drives data to the AMB in DIMM 3 via NB path 62.

A chipkill approach is employed to ensure that the present system can tolerate the failure of one of the RAM chips. The system is arranged such that the bits of any given data word stored in the first and second memory channels are interleaved across the RAM devices such that each RAM chip stores no more than one bit of the data word. This enables the system to tolerate the failure of a single RAM chip, as this results in the loss of just one bit of a given data word-which can be recovered via the word's ECC (assuming that each data word includes ECC bits capable of recovering one lost or corrupted data bit).

One way in which the bits of data words to be stored can be arranged is shown in FIG. 3. The bits of a 72-bit data word “A” are labeled “A₀, A₁, . . . , A₇₁”, a data word “B” would be labeled “B₀, B₁, . . . , B₇₁”, and so forth. As shown in FIG. 3, no more than one bit of any given data word is stored on a single RAM device; rather, the bits of a data word are evenly distributed between the two channels and the four DIMMs, with each of the 72 RAM chips storing one bit of the data word.

Note that the organization of data bits shown in FIG. 3 is merely exemplary-the bits of a data word could be distributed across the RAM chips in many different ways. It is only essential that the bits be organized such that no single RAM chip stores more than one bit of a given data word.

Data is conveyed on the SB and NB data paths in data frames 70. For the NB data path, each data frame is made up of two half-frames 72, 74. For the exemplary embodiment shown in FIG. 3, each half-frame contains 72 data bits. The first half-frame of a given frame should originate from one of the channel's two DIMMs (DIMM 2 for memory channel 50 in the example shown), and the second half-frame should originate from the channel's other DIMM (DIMM 1 in this case). As such, the contents of a given NB half-frame are determined by the contents of a corresponding DIMM. The data rate for data on the NB data path is preferably twice the data rate of data on the SB data path, and the NB data path is wider than the SB channel. This allows read throughput to be high and reduces read latency.

A given data frame is written to one of the channel's two DIMMs (e.g., DIMM 2 for memory channel 50 in the example shown), and the subsequent data frame is written to the channel's other DIMM (DIMM 1 in this case). As such, the contents of a given SB frame are determined by the contents of a corresponding DIMM.

The SB data path is preferably 10 bits wide, and the NB path is preferably between 12 and 14 bits wide, depending on the particular ECC scheme (if any) employed. In accordance with JEDEC specifications, a 14 bit wide NB path employs two bit lanes for CRC code bits, a 13 bit wide NB path has one CRC bit lane, and a 12 bit wide NB path accommodates no CRC bits. As such, a 72-bit group of data bits for a given half-frame is conveyed up a 12-bit wide NB path 12 parallel bits at a time, requiring six consecutive 12 bit groups to send the entire 72-bits. A 14-bit wide NB path would also require convey the data as six consecutive 12 bit groups, but would also include 2×6=12 CRC code bits. Similarly, a 72-bit group of bits on the SB path requires eight consecutive 10 bit groups to fill a data frame. The AMB device on each DIMM coordinates the transfer of data bits between its RAM devices and the SB and NB data paths.

Memory controller 54 issues write and read commands via the SB data path, with each command including an address. Both of the DIMMs on a channel respond to the same address, such that the two DIMMs essentially act as one DIMM.

The present invention provides an FB DIMM architecture which includes a chipkill functionality, but which only requires two memory channels. This is half the number of channels than might otherwise be needed. As such, significant savings are realized in terms of number of I/O pins (200-300 fewer than a comparable four channel implementation) and required PC board area (due to the reduced number of I/O pins) . Because the present scheme requires a response from two AMB devices to fill a frame in response to a read request—with one AMB filling the first half-frame and the second AMB filling the second half-frame —each AMB must differ slightly from the configuration specified by JEDEC.

The premise of the present invention could also be applied to an eight channel FB-DIMM architecture, to reduce it to four channels. Here, each of the four memory channels would contain 2 DIMMs, each of which is populated with x8 RAM chips and an AMB. Each channel is interfaced to a common memory controller via respective SB and NB data paths. As above, the architecture and protocol is arranged such that the bits of any given data word stored in the four memory channels are interleaved across the RAM devices such that each RAM stores no more than one bit of the data word.

The present invention enables the pinout requirements of an eight channel FB-DIMM architecture to be reduced by half, with a consequent reduction in space requirements. For example, a conventional eight channel architecture would comprise 8 DIMMs, each interfaced to the memory controller via respective SB and NB data paths. In a typical arrangement, such a system would store 72-bit data words, each DIMM would consist of 9 RAM chips and an AMB, and each RAM chip would be an x8-i.e., with 8 bits stored at each unique address.

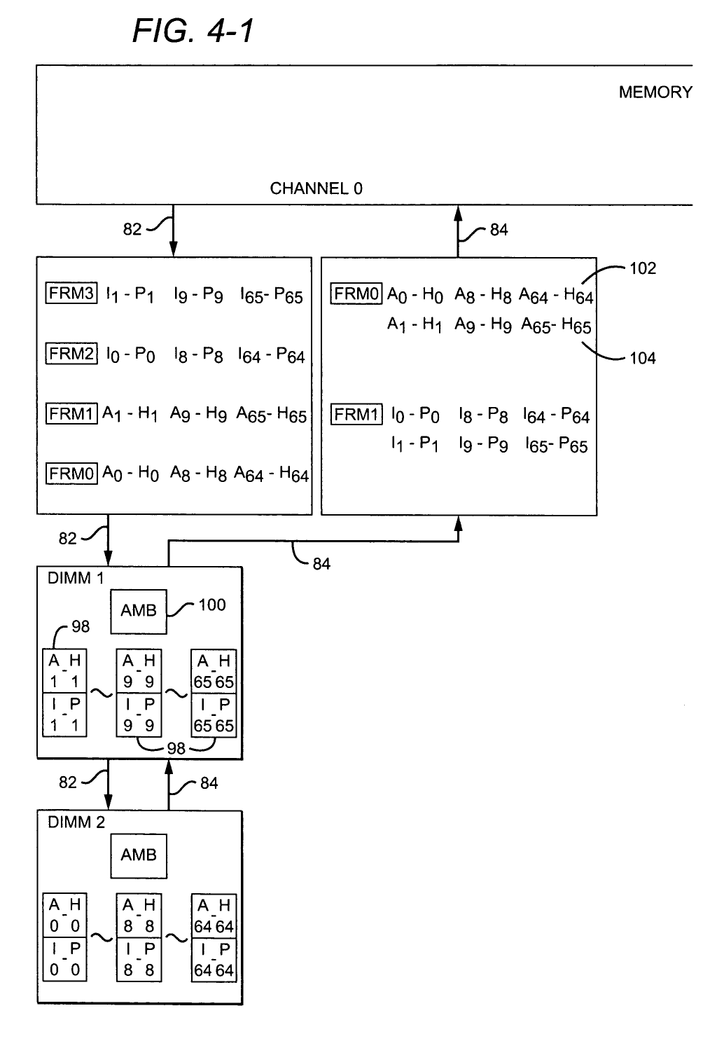

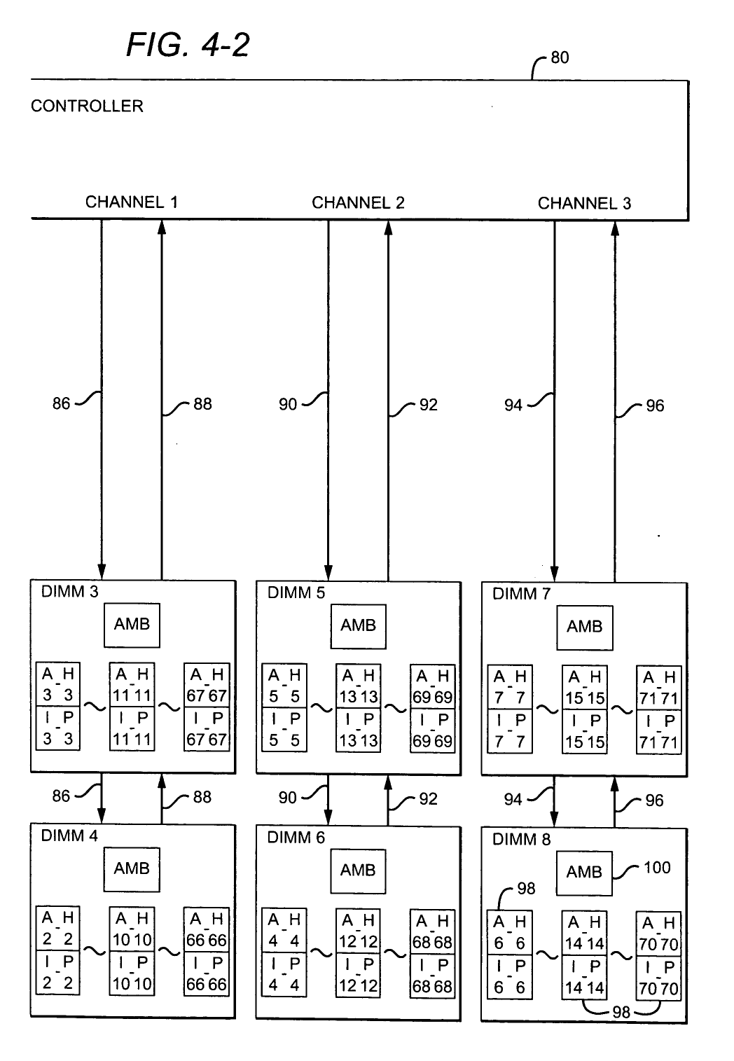

An exemplary four channel implementation in accordance with the present invention is shown in FIG. 4. Each of the four channels is serially-connected to 2 DIMMs via respective SB and NB data paths; all channels interface to a common memory controller 80. A first channel (channel 0) is connected to DIMMs 1 and 2 via SB path 82 and NB path 84, channel 1 connects to DIMMs 3 and 4 via SB path 86 and NB path 88, channel 2 connects to DIMMs 5 and 6 via SB path 90 and NB path 92, and channel 3 connects to DIMMs 7 and 8 via SB path 94 and NB path 96. Each DIMM holds nine x8 RAM devices 98 and an AMB 100.

The data words are suitably stored as shown in FIG. 4, with the data bits of any given word interleaved across the 72 RAM devices in the system, such that each RAM device stores no more than one bit of the data word. As before, data is written and read using data frames, with read requests fulfilled using first and second 72 bit half-frames. An example of how NB data bits might be organized for channel 0 is shown in FIG. 4, with the first half-frame 102 filled with bits from DIMM 2 and the second half-frame 104 filled with bits from DIMM 1. As above, a given data frame is written to one of a channel's two DIMMs (DIMM 2 for memory channel 0 in the example shown), and the subsequent data frame is written to the channel's other DIMM (DIMM 1 in this case).

While particular embodiments of the invention have been shown and described, numerous variations and alternate embodiments will occur to those skilled in the art. Accordingly, it is intended that the invention be limited only in terms of the appended claims.

I claim:

1. A fully buffered (FB) DIMM architecture and protocol, comprising:
a memory controller;
a first memory channel, comprising:
first and second DIMMS;
a southbound (SB) data path by which the data bits of x-bit wide data words are written to said first and second DIMMs; and
a northbound (NB) data path by which the data bits of x-bit wide data words are read from said first and second DIMMs, said southbound and northbound data paths connected between said memory controller and said first DIMM and between said first DIMM and said second DIMM such that said first and second DIMMs and said memory controller are serially-connected; and
a second memory channel, comprising:
third and fourth DIMMs;
a SB data path by which x-bit wide data words are written to said third and fourth DIMMs; and
a NB data path by which x-bit wide data words are read from said third and fourth DIMMs, said SB and NB data paths connected between said memory controller and said third DIMM and between said third DIMM and said fourth DIMM such that said third and fourth DIMMs and said memory controller are serially-connected;
each of said DIMMs comprising:
a plurality of RAM devices, each arranged to store y bits of data at respective addresses, said DIMM containing x/y of said RAM devices; and
an advanced memory buffer (AMB) device arranged to receive data from said SB and NB data paths, to encode/decode data for each of said DIMM's RAM devices, to redrive data received from said SB path to the next device on said SB path, and to redrive data received from said NB path to the next device on said NB path;
said FB DIMM architecture and protocol arranged such that all of the DIMMs on a given memory channel respond to an address placed on said channel's SB data path and such that the bits of any given data word stored in said first and second memory channels are interleaved across said RAM devices such that each RAM device stores no more than one bit of said data word.

2. The FB DIMM architecture and protocol of claim 1, wherein said data words are 72-bits in length, each of said RAM devices are x4 devices such that four bits of data are stored at each unique address, and each of said four DIMMs contains 72/4=18 RAM devices, said four DIMMs containing 72 RAM devices, each of which stores one bit of any given data word.

3. The FB DIMM architecture and protocol of claim 1, wherein data is conveyed on said NB data path in data frames comprising first and second half-frames, each of which contains a grouping of x data bits,
each first and second half-frame conveyed on the NB path of said first memory channel being read from said first and second DIMMs, respectively; and
each first and second half-frame conveyed on the NB path of said second memory channel being read from said third and fourth DIMMS, respectively.

4. The FB DIMM architecture and protocol of claim 1, wherein data is conveyed on said SB data path in data frames, each of which contains a grouping of x data bits, the bits of every other data frame conveyed on the SB path of said first memory channel being written to said first DIMM and the bits of the remaining data frames conveyed on the SB path of said first memory channel being written to said second DIMM; and
the bits of every other data frame conveyed on 10 the SB path of said second memory channel being written to said third DIMM and the bits of the remaining data frames conveyed on the SB path of said second memory channel being written to said fourth DIMM.

5. The FB DIMM architecture and protocol of claim 1, wherein the data rate of data on said NB data path is twice the data rate of data on said SB data path.

6. The FB DIMM architecture and protocol of claim 1, wherein any given data word comprises bits A₀, . . . , Aₓ₋₁, said bits evenly distributed across said RAM devices such that:
the x/y RAMs of DIMM 2 store bits A₀, A_{y}, A_{2*y}, . . . , A_{x-y},
the x/y RAMs of DIMM 1 store bits A₁,A_{y+1},A_{(2*y)+1}, . . . , A_{x-y+}, 5
the x/y RAMs of DIMM 4 store bits A₂,A_{y+2},A_{(2*y)+3}, . . . , A_{x-y+2}, and
the x/y RAMs of DIMM 3 store bits A₃,A_{y+3},A_{(2*y)+3}, . . . , Aₓ₋₁.

7. The FB DIMM architecture and protocol of claim 1, wherein said SB and NB data paths are further arranged to convey error correction code (ECC) bits for each of said data words.

8. The FB DIMM architecture and protocol of claim 1, wherein said SB data path is 10 bits wide and said NB data path is 14 bits wide.

9. A fully buffered (FB) DIMM architecture and protocol, comprising:
a memory controller;
a first memory channel, comprising:
first and second DIMMs;
a southbound (SB) data path by which the data bits of x-bit wide data words are written to said first and second DIMMs; and
a northbound (NB) data path by which the data bits of x-bit wide data words are read from said first and second DIMMs, said southbound and northbound data paths connected between said memory controller and said first DIMM and between said first DIMM and said second DIMM such that said first and second DIMMs and said memory controller are serially-connected; and
a second memory channel, comprising:
third and fourth DIMMs;
a SB data path by which x-bit wide data words are written to said third and fourth DIMMs; and
a NB data path by which x-bit wide data words are read from said third and fourth DIMMS, said SB and NB data paths connected between said memory controller and said third DIMM and between said third DIMM and said fourth DIMM such that said third and fourth DIMMs and said memory controller are serially-connected;
a third memory channel, comprising:
fifth and sixth DIMMs;
a SB data path by which x-bit wide data words are written to said fifth and sixth DIMMs; and
a NB data path by which x-bit wide data words are read from said fifth and sixth DIMMs, said SB and NB data paths connected between said memory controller and said fifth DIMM and between said fifth DIMM and said sixth DIMM such that said fifth and sixth DIMMs and said memory controller are serially-connected;
a fourth memory channel, comprising:
seventh and eighth DIMMs;
a SB data path by which x-bit wide data words are written to said seventh and eighth DIMMS; and
a NB data path by which x-bit wide data words are read from said seventh and eighth DIMMS, said SB and NB data paths connected between said memory controller and said seventh DIMM and between said seventh DIMM and said eighth DIMM such that said seventh and eighth DIMMs and said memory controller are serially-connected;
each of said DIMMs comprising:
a plurality of RAM devices, each arranged to store y bits of data at respective addresses, said DIMM containing x/y of said RAM devices; and
an advanced memory buffer (AMB) device arranged to receive data from said SB and NB data paths, to encode/decode data for each of said DIMM's RAM devices, to redrive data received from said SB path to the next device on said SB path, and to redrive data received from said NB path to the next device on said NB path;
said FB DIMM architecture and protocol arranged such that all of the DIMMs on a given memory channel respond to an address placed on said channel's SB data path and such that the bits of any given data word stored in said first and second memory channels are interleaved across said RAM devices such that each RAM device stores no more than one bit of said data word.

10. The FB DIMM architecture and protocol of claim 9, wherein said data words are 72-bits in length, each of said RAM devices are x8 devices such that eight bits of data are stored at each unique address, and each of said eight DIMMs contains 72/8=9 RAM devices, said eight DIMMs containing 72 RAM devices, each of which stores one bit of any given data word.
